(19) United States
(12) Patent Application Publication
(10) Pub. No.: US 2025/0172882 A1
(43) Pub. Date: May 29, 2025

(54) Method for evaluating at least one marker on a physical object for metrological detection of the object

(71) Applicant: ROBERT BOSCH GmbH, Stuttgart (DE)

(72) Inventors: Cedric Donie, Stuttgart (DE); Thomas Ludescher, Wimpfen (DE); Sergei Mishakin, Stuttgart (DE); Paul Frydlewicz, Ludwigsburg (DE)

(21) Appl. No.: 18/955,256

(22) Filed: Nov. 21, 2024

(30) Foreign Application Priority Data
Nov. 27, 2023 (DE) 10 2023 133 055.1

(51) Int. Cl. G03F 7/00

(52) U.S. Cl. CPC G03F 7/70683; G03F 7/706837; G03F 7/706841

(57) ABSTRACT

The invention relates to a method for evaluating at least one marker (200) on a physical object (50) for metrological detection of the object (50), comprising the following steps:
providing (101) at least one rendering of the marker (200), wherein the at least one rendering results in each case from a sensor detection,
determining (102) a reference marking (210) of the marker (200) on the basis of the provided rendering of the marker (200), wherein the reference marking (210) has at least two partial areas (220) of different display properties, wherein the determining (102) of the reference marking (210) comprises the following steps:
transforming (103) into one or more color spaces in the provided rendering of the marker (200) to display the at least two partial areas (220) of different display property with essentially the same display property,
recognizing (104) the reference marking (210) on the basis of the partial areas (220) displayed with essentially the same display property,
providing (105) a display of the at least two partial areas (220) with the different display property,
recognizing (106) at least one reference point of the reference marking (210) based on the provided display having the different display property.

The invention relates to a method for evaluating at least one marker on a physical object for metrological detection of the object. The invention further relates to such a marker, a computer program, and a device for this purpose.

### STATE OF THE ART

It is well known that photogrammetry can obtain certain information about physical objects from photographs. In many photogrammetry applications, several photos are combined to obtain a three-dimensional reconstruction with defined three-dimensional points on an object.

It is further known that two-dimensional fiducial markers (markers or photogrammetric markers) can be attached to an object in order to define a measuring point when measuring the object. Fiducial markers usually have a clearly defined reference point (often the center of a shape) and a code for unique identification.

Fiducial markers can fulfill various requirements. For example, it is important that they are reliably recognized by computer vision systems. The false-positive and false-negative rates should be kept as low as possible. In addition, the specific 3D position of the fiducial markers should be invariant against various types of distortions, such as perspective, affine and lens distortions. The ability to provide a variety of unique identifiers (IDs) from a family of reference markers that can be recognized using the same computer vision approach can also be of great importance. At the same time, it may be critical that the decoding of the fiducial markers is robust and has low error rates, even if they are partially occluded. Furthermore, false positive detections should be avoided, especially if the markers are reflected on a surface. When determining the reference point of the marker, both a repeatable (i.e. low scatter) and an accurate determination (i.e. with low systematic error) should be aimed for. The markers should have a small pattern size, but still be easily recognizable.

Fiducial markers can be categorized according to the type of shape used to locate the reference point and the type of code used to determine the unique ID. The shape used to locate reference points can be divided into circles, concentric rings, and line patterns. Fiducial marker codes can be divided into those based on patterns (special arrangement of features) and those based on barcodes (generally arranged in a circle as so-called “ring codes”).

### DISCLOSURE OF THE INVENTION

The object of the invention is a method having the features of claim 1, a marker having the features of claim 8, a computer program having the features of claim 10, and a device having the features of claim 11. Further features and details of the invention are apparent from the respective dependent claims, the description, and the drawings. Features and details which are described in connection with the method according to the invention naturally also apply in connection with the marker according to the invention, the computer program according to the invention, and the device according to the invention, and vice versa in each case, so that reference is or can always be made to the individual aspects of the invention reciprocally with regard to the disclosure.

In particular, the object of the invention is a method for evaluating at least one marker on a (in particular physical) object for metrological, in particular photogrammetric, detection of the object. The following steps may be provided, which are preferably computer-aided and/or automated:
providing at least one rendering, in particular mapping, of the marker, wherein the at least one rendering (e.g. as an image) can result in each case from a sensor detection (e.g. image detection) and/or wherein the rendering can comprise one or more image captures, in particular of the object,
determining a reference marking of the marker on the basis of the provided rendering of the marker, wherein the reference marking is preferably shaped as a circle or ring or an ellipse and/or has at least two partial areas of different display property, in particular color property, such as color, intensity, saturation, or the like, wherein preferably the partial areas are each shaped as a segment of a circle or ring.

Determining the reference marking can further comprise the following steps, in particular to evaluate the marker for metrological detection of the object:
transforming (transformation) of a color space and/or into one or more color spaces, in particular mapping or rendering into one or more color spaces, in the rendering of the marker provided, in order to render the at least two partial areas of different display property with essentially the same display property (e.g. luminosity or color),
recognizing the reference marking on the basis of the partial areas displayed with essentially the same display property,
providing a display (e.g. color space transformation) of the at least two partial areas with the different display property, preferably with different color or with different luminosity, in particular by performing a reverse transformation in accordance with the above transformation,
recognizing at least one reference point (in particular a center) of the reference marking on the basis of the provided display with the different display property, in particular by recognizing an intersection point of the partial areas in the display with different display property and preferably luminosity.

This has the advantage that the reference point can be reliably recognized in order to detect the object metrologically using this reference and/or to be able to further evaluate (e.g. decode) the marker. Transforming into one or more color spaces when rendering the marker can also be understood as transforming the mapping or rendering into one or more color spaces. In this way, the rendering can preferably be obtained in one or more transformed color spaces in order to achieve a different visualization of the rendering.

It may also be possible for the recognizing of the reference marking to be performed using a circle or ellipse detector and/or for the recognizing of the reference point, preferably the center, of the reference marking to be performed using an edge detector, for example. By separating the channels, an edge detector can be used to recognize the center with high accuracy by finding the intersection point of the partial areas or quarter circles.

Optionally, it can be provided that determining the reference marking comprises the following steps:
recognizing shapes, in particular circles, in the provided rendering of the marker using a shape and in particular circle or ellipse recognition detector, preferably algorithm,
checking the recognized shapes for plausibility using the different display properties and preferably different colors, preferably using a predefined plausibility specification,
recognizing one or more intersection points of the partial areas on the basis of the tested shapes in order to determine the reference point and/or preferably a center point as a result in each case, wherein the determined results can be combined with one another.

This makes it possible to check the plausibility of a recognized shape based on knowledge of the display properties used in order to be able to determine the partial areas more reliably.

It may further be possible for the marker to be designed as a ring-coded marker, wherein the reference marking can be surrounded by a concentric ring or ring segments that form a ring code. This allows further information to be obtained by evaluating the marker.

It is further conceivable within the scope of the invention that a non-symmetrical marking element is provided with the marker in order to indicate a starting position for decoding the ring code. This may, for example, be a “non-symmetrical marker center”, i.e. a non-symmetrical marking point as a marking element. This provides additional information that can be used to distinguish between different markers.

In a further possibility, it can be provided that the partial areas are designed as quarter circles, wherein adjacent partial areas differ in terms of their display property, preferably color.

It is further conceivable that the display property is a color, whereby the reference marking has a concentric edge that is designed with a different color than the partial areas or with one of the colors of the partial areas. This allows for improved recognition of the reference marking as well as error recognition when determining the position of the reference point.

Another object of the invention is a marker, in particular the marker pursuant to a method according to the invention, for attachment to a (in particular physical) object and for providing at least one reference point for metrological detection of the object. For this purpose, the marker can comprise a reference marking that has at least two partial areas with different display properties. In this case, the display properties of the partial areas can essentially show no difference or a smaller difference when the reference marking is rendered in a transformed color space compared to when the reference marking is rendered in its original color space or display property. The marker according to the invention thus has the same advantages as those described in detail with reference to a method according to the invention.

Another object of the invention is a computer program, in particular a computer program product, comprising instructions which, when the computer program is executed by a computer, cause the computer to execute the method according to the invention. The computer program according to the invention thus has the same advantages as those described in detail with reference to a method according to the invention.

Another object of the invention is a device for data processing that is configured to execute the method according to the invention. The device may, for example, be a computer which executes the computer program according to the invention. The computer may have at least one processor for executing the computer program. A non-volatile data memory may also be provided, in which the computer program is stored and from which the computer program can be read by the processor for execution.

Another object of the invention can be a computer-readable storage medium having the computer program according to the invention and/or comprising instructions which, when executed by a computer, cause the computer to execute the method according to the invention. The storage medium is configured, for example, as a data storage device such as a hard disk and/or a non-volatile memory and/or a memory card. The storage medium can, for example, be integrated into the computer.

In addition, the method according to the invention can also be designed as a computer-implemented method.

Further advantages, features and details of the invention are apparent from the following description, in which embodiments of the invention are described in detail with reference to the drawings. The features mentioned in the claims and in the description may be essential to the invention individually or in any combination. In the figures,

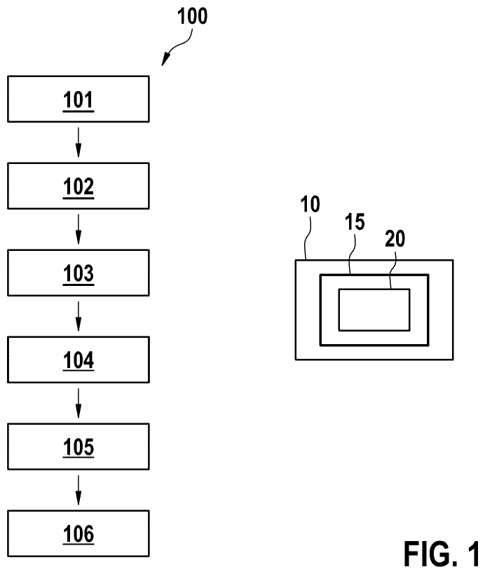

FIG. 1 shows a schematic visualization of a method, a device, a storage medium, and a computer program according to embodiments of the invention.

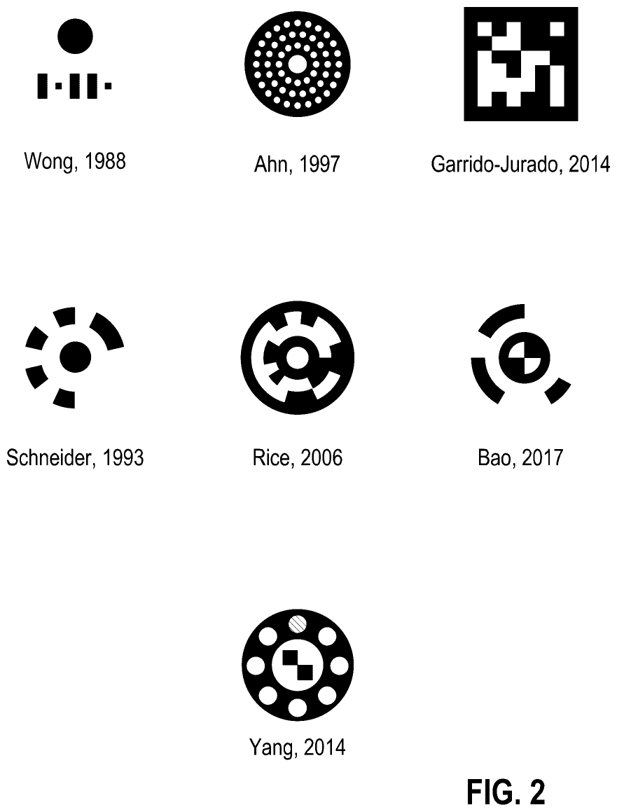

FIG. 2-4 show a schematic representation of various fiducial markers.

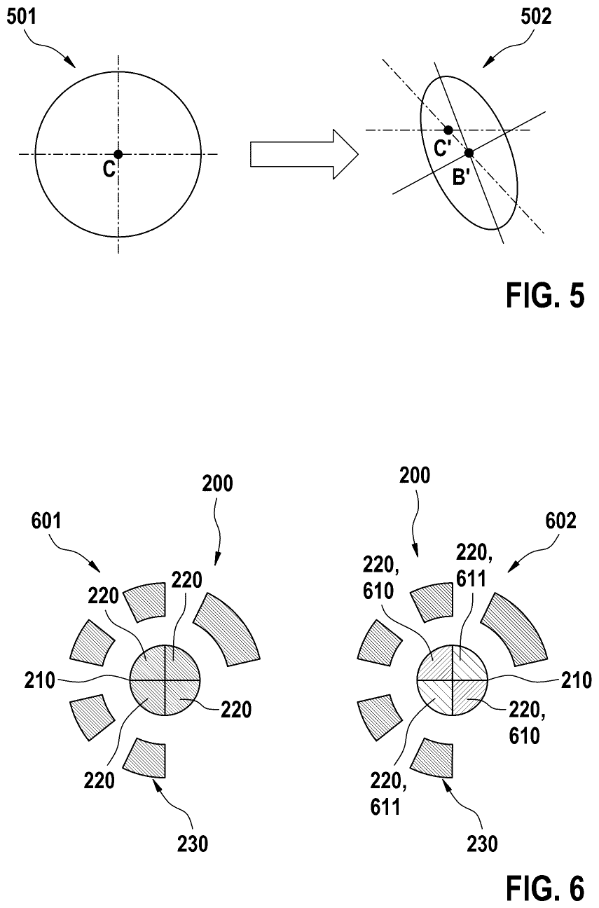

FIG. 5 shows an illustration of an eccentricity of a projection of a circle.

FIG. 6 shows a schematic representation of a marker according to embodiments of the invention.

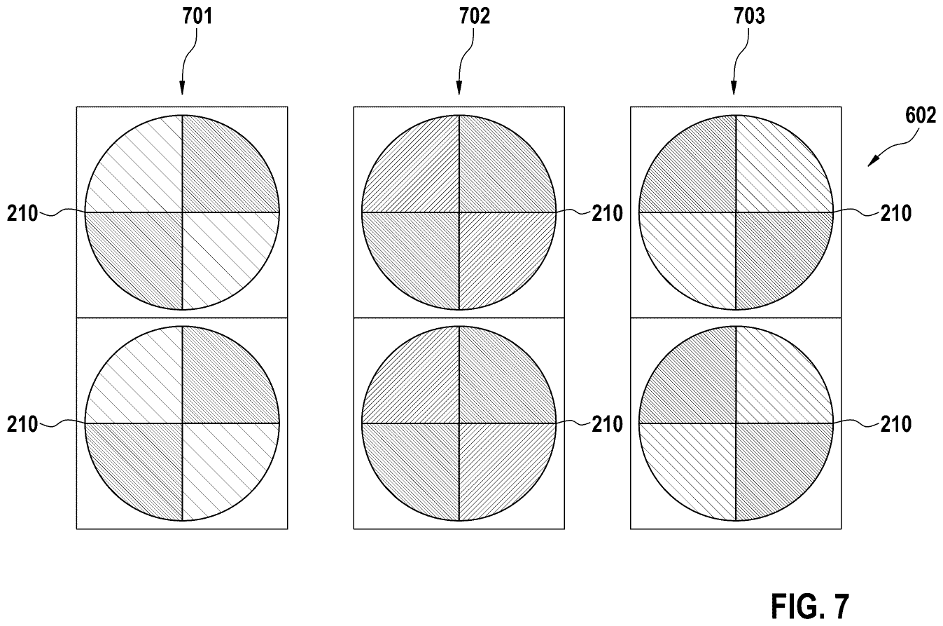

FIG. 7 shows schematic visualization of a transformation according to a method according to embodiments of the invention.

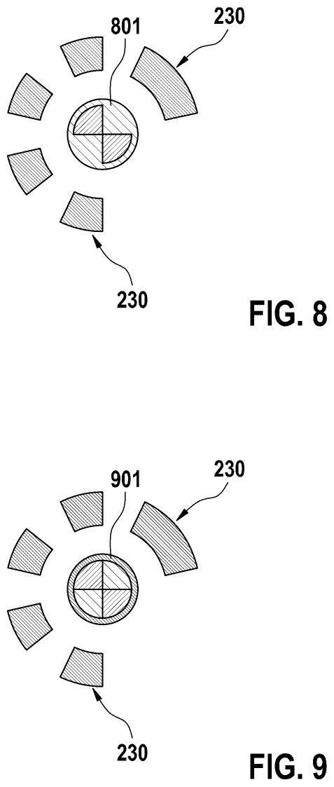

FIGS. 8-12 show further schematic representations of a marker according to embodiments of the invention.

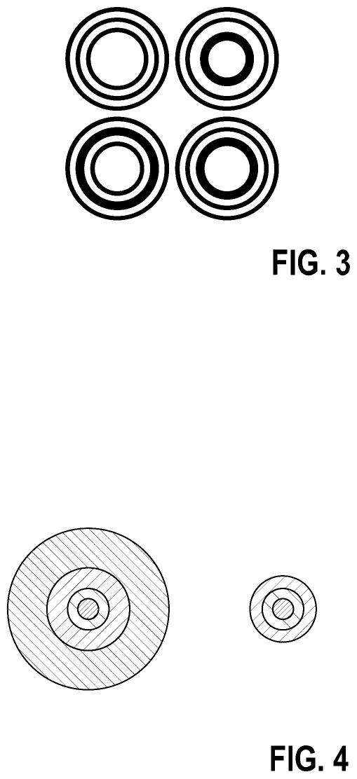

The most common reference markings use circles to locate the reference point (e.g. the center of the circle). Circles are easy to recognize at both large and small scales, see FIG. 2 for some examples 201. Instead of a single reference point, concentric rings can also be used to localize reference points (see also L. Calvet, P. Gurdjos and V. Charvillat, “Camera tracking using concentric circle markers: Paradigms and algorithms,” 2012 19th IEEE International Conference on Image Processing, Orlando, FL, USA, 2012, pp. 1361-1364, doi: 10.1109/ICIP.2012.6467121). The concentric rings enable the determination of the marking plane and a more accurate determination of the marking center point (by extrapolating the change in center point position as the circular contours become smaller). Instead of relying on a circle with an ambiguous center point, reference points can also be represented by the intersection of lines or edges to obtain a clearly defined point. These are not affected by (perspective) distortions as the intersection point is infinitesimally small. See also FIGS. 2 and 3 for several other examples. Further examples of fiduciary markers can be found in Liu, 2021.

Fiducial markers based on ring codes can also have a feature that serves as a marking center (often a circle) surrounded by the code, often as a ring code or as a code of varying thickness. The ring-coded markers according to Schneider, 1993 (Optical 3-D-Measurement Systems for Quality Control in Industry. AICON-Industrial Photogrammetry and Image Processing, 1993) are probably the most commonly used photogrammetric markers.

Another important marker is a line pattern center in combination with ring coding according to Bao, 2017 (“A robust recognition and accurate locating method for circular coded diagonal target,” Proceedings Volume 10458, AOPC 2017: 3D Measurement Technology for Intelligent Manufacturing; 104580Q (2017), https://doi.org/10.1117/12.2283523). This marker combines the simple and robust decoding and high information content of ring codes while providing a well-defined center. Color-coded fiducial markers have also been used to allow, for example, the recognition of markers at very different scales. So-called pattern-based fiducial markers are based on the particular alignment of patterns that represent the code of the fiducial marker. A QR code is a simple example of this. Examples of fiducial markers with circles of different diameters in different colors are also shown in FIG. 4, where the different colors are illustrated with different hatching.

Each type of form for displaying reference points has advantages and disadvantages. Circles are the easiest target to recognize, but the exact location of the circle center is not possible in distorted images. Targets with line patterns are more difficult to recognize in an image, but the reference point is clearly defined. Concentric ring targets are somewhat easier to recognize (compared to line patterns) and allow better center localization (than circular targets), but the number of codes is limited.

Markings with a single circle in the center (these are usually ring-coded) are easy to recognize at different scales. However, the center cannot be accurately determined if the marker is distorted or eccentric, as the center of the ellipse in 2D no longer matches the center of the marker in 3D. This problem means that multiple images of the marker will result in different centers (random error), and that the center may also be incorrect across multiple measurements depending on (perspective) distortion (systematic error due to eccentricity). FIG. 5 illustrates the eccentricity of a projection of a circle in which the object plane 501 is projected onto the image plane 502 via a perspective projection. C indicates the reference point or center, C′ the projection of C and B′ the center of the ellipse.

The random error can be reduced by increasing the number of measurements, but this may not be feasible or too costly. The systematic error cannot be reliably reduced. The diagonal line pattern instead of a circle introduced by Bao, 2017 improves the reference localization of ring-coded markers. However, the diagonal element is more difficult to recognize than a circle, which eliminates an important advantage of the markers of Schneider, 1993.

Markers with multiple concentric rings reduce the position error of the reference point somewhat (compared to circles), as the error can be extrapolated from different scales. However, concentric markers offer fewer possible IDs, require a higher resolution or larger images and are more difficult to recognize than ring-coded markers with circles in the middle (see FIG. 3).

Ring-coded markers can be mapped with different rotation angles. Therefore, it is not immediately clear where the ring code begins, leading to different possible code interpretations for a single coded marker. Thus, the ring code may contain some form of redundancy to ensure rotational invariance. This redundancy reduces the number of codes available. The circles look the same regardless of rotation, so it is not possible to determine how a marker is rotated. It is therefore not clear where a ring code surrounding the marker begins, and a ring code on a marker can result in multiple IDs unless the number of codes is reduced to avoid ambiguity. Many ring-coded markers also result in valid but different codes when mirrored.

FIG. 1 shows schematically, according to embodiments of the invention, a method 100, a device 10, a storage medium 15, and a computer program 20. In particular, an improved marker is proposed. Specifically, the method 100 can be used to evaluate at least one marker 200 on a physical object 50 for a metrological and, in particular, photogrammetric detection of the object 50. According to a first method step 101, at least one rendering of the marker 200 can be provided first. The at least one rendering can, for example, result in each case from a sensor detection, wherein the rendering can preferably comprise one or more image captures. According to a second method step 102, a reference marking 210 of the marker 200 can be determined on the basis of the provided rendering of the marker 200. For example, the provided rendering is processed and evaluated in the form of a digital image. The reference marking 210 can be shaped as a circle or ring or an ellipse. In particular, the at least two partial areas 220 have a different display property under at least one color-space transformation, such as different color properties, such as color, intensity, saturation, and the like. The partial areas 220 may each be shaped as a segment of a circle or ring.

According to embodiments of the invention, the determining 102 of the reference marking 210 comprises the following steps:
transforming 103 the color space in the provided rendering of the marker 200 to display the at least two partial areas 220 of different display properties with substantially the same display properties, e.g. luminosity or color.
recognizing 104 the reference marking 210 based on the partial areas 220 displayed with substantially the same display property.
providing 105 a display of the at least two partial areas 220 with the different display property, preferably color or different luminosity, in particular by performing a reverse transformation according to the transformation of 103.
recognizing 106 at least one reference point, preferably/for example center, of the reference marking 210 on the basis of the provided display with the different display property, in particular by detecting an intersection point of the partial areas 220 in the display with different display property, preferably luminosity.

According to embodiments of the invention, a marker is proposed which can provide precise localization, even in eccentric or distorted images. In grayscale images (or in another suitable color space transformation 103), the markers may be backward compatible with software suitable for recognizing ring-encoded markers, in particular Schneider, 1993, possibly without gaining accuracy. Since the localization advantageously does not depend on the determination of the ellipse center, the size of the marker center can be increased to improve the recognition without reducing the accuracy. Due to the lower rotational ambiguity, the number of codes can be increased.

The use of color with the marker allows more information to be provided, so the risk of false positives is lower compared to other approaches (filtering out candidates is possible). In grayscale images, the marker is as easy to see as a circle, but when separated by color channels, the center of the marker can be located as precisely as with line pattern targets.

According to embodiments of the invention, a ring-coded marker 200 is therefore provided, in which a reference marking 201 in the form of a circle 210 in the center of the ring-coded marker 200 is divided into partial areas 220 with two different colors of ideally the same luminosity. In FIG. 6 and in FIGS. 8 to 12, the different colors are illustrated by different hatching. The different colors can be red 610 and blue 611, for example.

In the embodiment example shown in FIG. 6, the partial areas 220, preferably quarter circles 220, of the reference marking 210 are alternately formed in the different colors (red 610 or blue 611) in a clockwise direction. In a grayscale image 601, the colors (ideally) have the same luminosity, and the image looks like a black or uniform gray circle, so that a circle or ellipse detector can be applied to the grayscale image. By separating the channels, an edge detector can be used to detect the center with high accuracy by finding the intersection point of the partial areas 220 or quarter circles 220.

More generally, it may be an inventive idea that a display property such as colors 610, 611 with ideally equal luminosity (or equal color under any color transformation) are used to create simple shapes in grayscale 601 (or transformed color space 601) that allow for straightforward image processing. When viewing different color channels (or other color space transformations) 602, more complex shapes can become visible, providing additional information (see FIG. 6). In photogrammetry, this provides the best of both worlds between simple or easy to recognize yet inaccurate markers 200 and complex or difficult to recognize yet information-rich and accurate markers 200.

The design of the marker 200 shown in FIG. 6 according to embodiments of the invention is an arrangement of four quarter circles 220, wherein the adjacent quarter circles 220 may have different colors 610, 611, but approximately the same luminosity. This marker 200 can be applied to the surface to be measured in various ways, for example by laser printing on adhesive foil. The colors of the marker 200 can have a different luminosity than the background in order to obtain a higher contrast.

A method according to embodiments of the invention may comprise the following steps for recognizing and decoding the photogrammetric markers. First, according to a first step, images may be taken with a digital camera or other sensor as a rendering of the marker, thus containing the proposed markers and preferably fiducial markers. Subsequently, the image may be converted to grayscale, whereby initially only the luminosity information may be considered. According to a further step, a suitable circle recognition algorithm can recognize all circle centers in the images. According to an optional step, the recognized circles can be checked for plausibility based on the color and circles without the expected color pattern can be discarded. Furthermore, the colors of the circle can be separated according to chroma (color), e.g. by considering only the red channel. The intersection point of the color gradients can then be determined using a suitable algorithm to determine the center of the marker. Furthermore, these steps can be repeated in another color channel to find the center of the marker and this result can be combined with the previous result. In this way, the recognition quality can be improved.

The decoding of the barcode can be simplified by aligning the start of the barcode (or a fixed offset) radially to the edge of one of the middle quarter circles. In this way, there are only four (or two if, for example, you have to start at the border from red to blue) instead of, for example, 8 starting positions (for 14-bit codes).

It is possible to use different color separation schemes, e.g. only the red channel, only the blue channel, the hue in the HSV color model or a combination of several to distinguish between the different colors.

The parts of the center of the circle do not have to have the same luminosity, just a different color. Instead of being resolved into a circle in grayscale, the features can be resolved into a circle under any color transformation. For example, magenta and yellow of unequal luminosity could be the two colors; prior to being recognized, magenta and yellow would be mapped to black and the image converted to grayscale; the former magenta and yellow would now form a homogeneous black circle.

It is conceivable that if the brightness (or display according to 103) is not exactly the same or due to chromatic aberration, the edges of the quarter circle 220 may be visible in the grayscale image 601 or in another color channel image (see FIG. 7, where the color channels red 701, green 702 and blue 703 are shown as examples), which could lead to lower accuracy in contour-based circular detectors. Therefore, according to embodiments of the invention, a border 801 in one of the two colors may be added to the reference marking 210, as shown in FIG. 8.

Building on the idea from the previous section, a different colored edge ring 901 could also be used instead of a ring of the same color 801 around the center of the reference marking 210 (see FIG. 9). This would enable the detection of concentric rings on the grayscale image with the advantage that a lower false-positive rate is possible at the beginning of the process, since rings are less frequent. Furthermore, a plausibility check of the location can be possible by combining the center-of-concentric-ring approach and the intersection of lines. Also, an estimation of the orientation of the marker can result in more degrees of freedom and enable backward compatibility with other conventional markers.

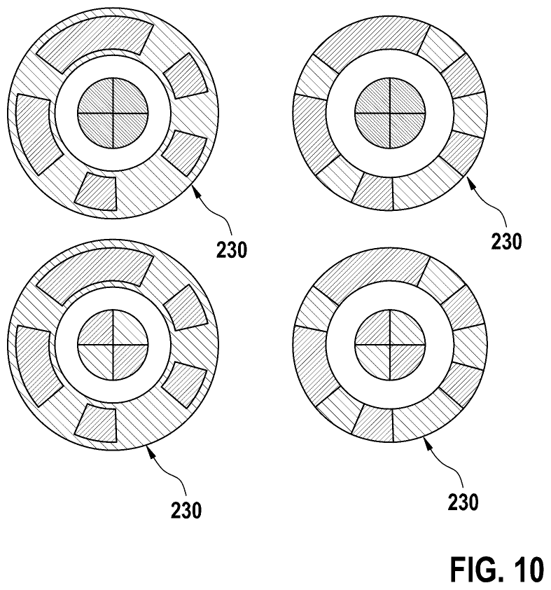

The ring code 230 can also be filled with different colors so that a ring code is created when separated by color channels and a concentric ring is created in the grayscale image. This is shown as an example in FIG. 10, where the different colors are illustrated by different hatching. In this way, the markings can be combined with the advantages of concentric circles and the recognition of the ring code can be improved, as a ring code detector can simply be used in the grayscale image. For example, concentric rings can be used to determine more degrees of freedom from a single marking, which is an improvement over circular markings.

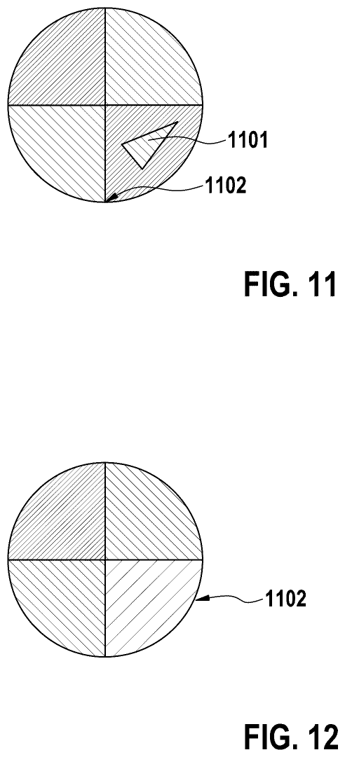

Any non-ordinary color in the code ring 230 (even a single color such as a red bar code on a white background) improves concealment resistance unless the concealing object is the same color as the code (concealing objects are usually black or silver). Another use of color is to ensure reflection invariance by using color to create a non-symmetric mark 1101. For example, it could be used to check whether the triangle in FIG. 11 is pointing counterclockwise (this example also provides rotation invariance). Furthermore, a starting position 1102 of the ring coding can be determined in this way.

The use of more than two colors offers further advantages. Three colors reduce the possible starting positions to a single starting position 1102 for the ring code (see FIG. 12) without the need to recognize special geometric elements. In FIG. 11, the triangle could also be replaced by another color, e.g. green; this would further simplify the recognition, since the green triangle could be recognized on the basis of the color and not the shape and then the intersection point of the lines would be omitted for the recognition.

Instead of using asymmetric circles, rotational invariance (without reducing the number of codes) can be achieved by having the ring code 230 start at the transition from one color to the next in a particular direction (e.g., from red to blue) and having a ring code 230 with a number of bits that is not a multiple of four (more generally, the number of sectors in the center). The proposed idea also makes the marking insensitive to reflections. The use of color in fiducial markers allows the reduction of reflections on most colored reflective surfaces (such as car paint). The number of different colors and/or sectors in the center can be increased indefinitely. In addition, the center can be an ellipse instead of a circle in grayscale. Matching the apochromatic (or super apochromatic, etc.) properties of the lens to the marker colors makes it possible to eliminate (as far as possible) chromatic aberration. In this case, the light reflected by the marker is not full spectrum but has specific wavelengths that can be selected to match the wavelengths at which the objective has minimal chromatic aberration. The proposed markers 200 can also be used to calibrate sensors for autonomous driving vehicles.

The foregoing description of the embodiments describes the present invention solely by way of examples. Of course, individual features of the embodiments may be freely combined with one another, provided that this is technically expedient, without departing from the scope of the present invention.

The description also refers to several sources in short form, which are listed in full below:
Wong, 1998: WONG, Kam W.; LEW, Michael; WILEY, Anthony G. 3D metric vision for engineering construction. International Archives of Photogrammetry and Remote Sensing, 1988, vol. 27, no. B5, pp. 647-656.
Ahn, 1997: 4th ABW Workshop Optische 3D-Formerfassung, TA Esslingen 22-23.01.1997At: Esslingen, German;
Garrido-Jurado, 2014: https://doi.org/10.1016/j.patcog.2014.01.005
Schneider, 1993: SCHNEIDER, Carl-Thomas; SINNREICH, Kurt. Optical 3-D measurement systems for quality control in industry. International Archives of Photogrammetry and Remote Sensing, 1993, vol. 29, pp. 56-56. (isprs.org) (See also DE19733466B4)
Rice, 2006: https://doi.org/10.1016/j.pmcj.2006.07.006
Bao, 2017: A robust recognition and accurate locating method for circular coded diagonal target (https://doi.org/10.1117/12.2283523).
Yang, 2014: https://doi.org/10.1016/j.ijleo.2014.03.009
Liu, 2021: A Novel Concentric Circular Coded Target, and Its Positioning and Identifying Method for Vision Measurement under Challenging Conditions https://doi.org/10.3390/s21030855.

1. A method for evaluating at least one marker on a physical object for metrological detection of the object, comprising the following steps:
providing at least one rendering of the marker,
wherein the at least one rendering results in each case from a sensor detection,
determining a reference marking of the marker on the basis of the provided rendering of the marker, wherein the reference marking has at least two partial areas with different display properties,
wherein the determining of the reference marking comprises the following steps to evaluate the marker for the metrological detection of the object:
transforming into one or more color spaces in the provided rendering of the marker to render the at least two partial areas of different display property with substantially the same display property,
recognizing the reference marking on the basis of the partial areas displayed with essentially the same display property,
providing a display of the at least two partial areas with the different display property, and
recognizing at least one reference point of the reference marking on the basis of the provided display with the different display property.

2. The method according to claim 1,
characterized in that
the recognizing of the reference marking is performed using a circle or ellipse detector, and in that the recognizing of the reference point of the reference marking is performed, for example, using a gradient detector, edge detector, or histogram approach.

3. The method according to claim 1,
characterized in that
the determining of the reference marking comprises the following steps:
recognizing shapes, in particular circles or ellipses, in the provided rendering of the marker using a shape and in particular circle or ellipse recognition algorithm,
checking the recognized shapes for plausibility using the different display properties,
recognizing one or more intersection points of the partial areas on the basis of the tested shapes in order to determine the reference point as a result in each case, wherein the determined results are combined with one another.

4. The method according to claim 1,
characterized in that
the marker is designed as a ring-coded marker, wherein the reference marking is surrounded by ring segments or concentric rings that form a ring code.

5. The method according to claim 4,
characterized in that
a non-symmetrical marking element is provided at the marker to indicate a starting position for decoding the ring code.

6. The method according to claim 1,
characterized in that
the partial areas are designed as quarter circles, adjacent partial areas differing with respect to their display property.

7. The method according to one of the preceding claims,
characterized in that
the display property is a color, wherein the reference marking has a concentric edge which is designed with a different color than the partial areas.

8. The method according to claim 1,
characterized in that
the marker is designed as a ring-coded marker, wherein the color space of the provided rendering of the marker is transformed according to a first transformation such that a continuous ring of the ring-coded marker is obtained and is transformed according to a second transformation such that a decodable rendering of the ring-coded marker is obtained.

9. A marker for attachment to a physical object and for providing at least one reference point for metrological detection of the object, comprising a reference marking having at least two partial areas with different display properties, wherein the display properties of the partial areas have essentially no difference or a smaller difference when the reference marking is rendered in a transformed color space compared to when the reference marking is reproduced in separate color channels and/or under any color space transformation.

10. The marker according to claim 9,
characterized in that
the marker is used as at least one evaluated marker.

11. A tangible non-transitory computer program, comprising instructions which, when the computer program is executed by a computer, cause the computer to:
provide at least one rendering of the marker, wherein the at least one rendering results in each case from a sensor detection, and
determine a reference marking of the marker on the basis of the provided rendering of the marker, wherein the reference marking has at least two partial areas with different display properties,
wherein the determining of the reference marking comprises the following steps to evaluate the marker for the metrological detection of the object:
transforming into one or more color spaces in the provided rendering of the marker to render the at least two partial areas of different display property with substantially the same display property,
recognizing the reference marking on the basis of the partial areas displayed with essentially the same display property,
providing a display of the at least two partial areas with the different display property, and
recognizing at least one reference point of the reference marking on the basis of the provided display with the different display property.

12. A device for data processing,
the device comprising:
a processor; and
a memory storing commands that, when executed by the processor, cause the processor to:
provide at least one rendering of the marker, wherein the at least one rendering results in each case from a sensor detection, and
determine a reference marking of the marker on the basis of the provided rendering of the marker, wherein the reference marking has at least two partial areas with different display properties,
wherein the determining of the reference marking comprises the following steps to evaluate the marker for the metrological detection of the object:
transforming into one or more color spaces in the provided rendering of the marker to render the at least two partial areas of different display property with substantially the same display property,
recognizing the reference marking on the basis of the partial areas displayed with essentially the same display property,
providing a display of the at least two partial areas with the different display property, and
recognizing at least one reference point of the reference marking on the basis of the provided display with the different display property.

13. The method according to claim 1, characterized in that reference point is a center of the reference marking.

14. The method according to claim 3 further comprising checking the recognized shapes for plausibility using different colors.

15. The method according to claim 3 further comprising recognizing the one or more intersection points of the partial areas on the basis of the tested shapes in order to determine the reference point and a center point.

16. The method according to claim 6, wherein the adjacent partial areas differ with respect to their color.
